(19) United States
(12) Patent Application Publication
(10) Pub. No.: US 2013/0320385 A1
(43) Pub. Date: Dec. 5, 2013

(54) Method for Producing a Radiation Conversion Element, Radiation Conversion Element and Optoelectronic Component Containing a Radiation Conversion Element

(71) Applicants: Mikael Ahlstedt, Muenchen (DE); Raquel de la Pena Alonso, Neubiberg (DE)

(72) Inventors: Mikael Ahlstedt, Muenchen (DE); Raquel de la Pena Alonso, Neubiberg (DE)

(73) Assignee: OSRAM OPTO SEMICONDUCTORS GMBH, Regensburg (DE)

(21) Appl. No.: 13/990,774

(22) PCT Filed: Dec. 7, 2011
(86) PCT No.: PCT/EP2011/072067

§ 371 Date: Aug. 23, 2013

(30) Foreign Application Priority Data
Dec. 13, 2010 (DE) 10 2010 054 279.2

(51) Int. Cl. G02B 5/00; H01L 33/50

(52) U.S. Cl. CPC G02B 5/00; H01L 33/50
USPC 257/98; 250/458.1; 427/162

(57) ABSTRACT

A method for producing a radiation conversion element is provided, in which a solution is applied to a substrate, a gel is formed from the solution and the gel is thermally treated. A radiation conversion element is also provided which is produced according to the method. An optoelectronic component is also provided which contains a radiation conversion element.

This patent application is a national phase filing under section 371 of PCT/EP2011/072067, filed Dec. 7, 2011, which claims the priority of German patent application 10 2010 054 279.2, filed Dec. 13, 2010, each of which is incorporated herein by reference in its entirety.

### TECHNICAL FIELD

A method for producing a radiation conversion element as well as the radiation conversion element and an optoelectronic component having the radiation conversion element is provided.

### BACKGROUND

Radiation conversion elements can be applied, e.g., to semiconductor chips of radiation-emitting, optoelectronic components such as, e.g., LEDs. The LEDs emit light of a specific wavelength which can be converted by the radiation conversion element into light of a different wavelength.

### SUMMARY OF THE INVENTION

Embodiments of the invention provide a simple-to-implement method for producing a radiation conversion element, by means of which a radiation conversion element having improved properties can be produced. Further embodiments provide the radiation conversion element and an optoelectronic component which contains the radiation conversion element.

A method is provided for producing a radiation conversion element including the method steps A) providing a substrate and a stable solution which comprises luminescent dopant precursors, B) applying the solution to the substrate, C) hydrolyzing and condensing the solution to form a gel, D) thermally treating the gel to form a conversion layer on the substrate. The conversion layer produced by this method can have a crystalline or glass-like, i.e., amorphous, structure. In connection with the finished conversion layer, the term “amorphous” is understood hereinafter to mean that crystalline dopant particles can be present therein.

In connection with dopant precursors, the term “precursor” refers to compounds which in the course of method undergo chemical reactions and are thus changed, but from the outset contain the actual dopant, as present in the conversion layer after method step D).

By means of this method, a solution having luminescent properties is applied to the substrate and is formed into a gel layer. The gel layer which in method step D) continues to be thermally treated and is thus formed into a crystalline or amorphous conversion layer containing a dopant is able—by reason of the luminescent dopants present in the layer—to convert radiation of one wavelength into a larger or smaller wavelength depending on the type of dopant.

The substrate can also have radiation-converting properties, which means that the conversion layer can convert the already converted radiation even further and thus can effect fine-tuning of the converted wavelength and therefore the color impression for someone observing the emitted light from the outside. For example, a white light-emitting device, in whose beam path a radiation conversion element having the aforementioned properties is applied, can thus emit a cool-white light for car lighting or a warm-white light for lighting in homes.

By means of the method, it is possible in a convenient manner to deposit a conversion layer on the substrate and thus obtain a radiation conversion layer which is dense and has homogeneous doping and a small thickness. By virtue of the fact that this method can be performed in a convenient manner it can also be used industrially.

The hydrolysis and condensation in method step C) leads to cross-linking of the solution and thus to the formation of a gel. The reactions which occur during the hydrolysis and condensation are stated in the formulae (I) to (III):

Rn-xM(OR)x+xH2O [symbol] Rn-xM(OH)x+xROH (I)

Rn-xM(OH)x+Rn-xM(OH)x [symbol] (R)n-xM(OH)x−1-O-M(OH)x−1(R)n-x+(x−1)HOH (II)

Rn-xM(OH)x+Rn-xM(OR)x [symbol] (R)n-xM(OH)x−1-O-M(OR)x−1(R)n-x+(x−1)ROH (III)

In all of the formulae, “R” stands for an organic moiety, e.g., unbranched or branched alkyl groups of any length. The organic moieties in the mutually reacting molecules can be the same or different. “M” stands for a metal which can be selected depending upon how the conversion layer formed by the method is to be composed. “n” stands for the valency of the metal, upon which the number of moieties bonded to M depends.

Formula (I) shows the hydrolysis of a substituted metal alkoxide with water, in which a metal, which is substituted with x hydroxy groups and n-x organic moieties, and an alcohol are produced.

In accordance with formula (II), water can be condensed from two metal compounds which are each substituted with x hydroxy groups and n-x organic moieties. In accordance with formula (III), this can also occur between a metal, which is substituted with x hydroxy groups and n-x organic moieties, and a metal alkoxide. The reactions in accordance with formula (II) and (III) are reversible. The pattern of reaction in accordance with formulae (I) to (III) can also be defined as sol-gel chemistry.

The hydrolysis and condensation in method step C) can be effected at room temperature.

In accordance with one embodiment, a solvent and metal precursors can also be added to the stable solution in method step A). Suitable solvents can be, e.g., alcohols, such as isopropanol or ethanol, or acid/base catalysts, such as water with HCl or NH₃. The solvent serves to suitably dilute the solution and influence the drying rate and homogenization of the solution. Depending upon the drying rate, the viscosity of the resultant gel can be influenced.

In connection with metal precursors, the term “precursor” refers to compounds which in the course of the method undergo chemical reactions and are thus changed, but from the outset contain the metal which is present in the conversion layer after method step D).

Metal precursors which are added to the solution can be selected from a group comprising metal alkoxides, metal acetates, metal chlorides and metal nitrates. The metals of these compounds can be selected, e.g., from a group comprising Al, Si, Ti and Zr. In general, metal alkoxides have the formula M-O—R. M stands for the metal, R stands for an organic moiety which can be randomly selected.

In addition, water can also be added to the solution, in order to promote hydrolysis. Furthermore, in order to stabilize the solution a complexation agent can be added. An example of a complexation agent is acetyl acetate. The ratio of the metal of the dopant precursor to all metals in the solution can be 0.5 to 20.

The dopant precursors in method step A) can be selected from a group which comprises metal alkoxides, metal acetates, metal chlorides and metal nitrates of the metals Eu, Ce, Ir, Er and Cs. The dopant precursors can also be present as nanopowder which is dispersed in the solution. Therefore, the solution has luminescent dopant precursors added to it which in method step C) form a gel together with the metal precursors in the solution in accordance with the reactions of formulae (I) to (III), i.e., cross-link with each other. The metals of the metal precursors and the metals of the dopant precursors are thereby incorporated into the network.

The application in method step B) can be performed by means of a method which is selected from a group comprising spin coating, dip coating or spray coating. By means of these methods, particularly thin layers can be applied, with which after gel formation and thermal treatment a thin conversion layer which has radiation-converting properties can result. A small thickness of the conversion layer on the substrate ensures that the conversion layer is formed substantially transparent.

The application methods which are used in method step B) are particularly cost-effective methods in comparison with conventional application methods, such as, e.g., CVD, PVD or sputtering.

Application by means of spin coating renders it possible to adjust the thickness of the resulting conversion layer and the wavelength, to which radiation is converted, which in turn is determined by the precisely adjustable thickness.

If, e.g., an LED having a radiation conversion element is to be provided, the conversion layer should be as transparent as possible. Radiation-converting materials which convert radiation into wavelengths in the green or red range frequently have non-cubic crystal structures, whereby it is difficult to introduce them into transparent materials. Therefore, it is important to form these materials as thinly as possible as a radiation-converting, crystalline or amorphous conversion layer on the substrate, so that its intrinsic absorption and scattering is reduced. This can be achieved by a method as described above.

Method step D) can comprise the steps D1) drying the gel, D2) calcining the gel to form an amorphous layer, D3) pyrolysing the amorphous layer to form a conversion layer. The luminescent dopant is thus incorporated in the conversion layer.

Therefore, the thermal treatment in method step D) is divided into three partial steps. First, the gel is dried for several minutes at slightly elevated temperatures, e.g., a temperature from the range of 60° C. to 180° C., then calcined at higher temperatures, e.g., a temperature from the range of 400° C. to 600° C., and finally subjected to pyrolysis, e.g., at a temperature from the range of 600° C. to 1800° C. The pyrolysis atmosphere can be an oxygen, nitrogen or forming gas atmosphere.

By means of the calcination, the gel layer can produce an amorphous layer which is then formed by the pyrolysis into a conversion layer which is crystalline or amorphous. If the conversion layer is amorphous, crystalline dopant particles can be incorporated therein.

In one embodiment, method steps B) to D) can be repeated at least twice. Therefore, at least two, but also several radiation-converting conversion layers lying one on top of the other can be applied to the substrate. Repetition of up to eight times is likewise feasible. The repeated application of the solution to the substrate in method step B) can be effected after method step D1), after method step D2) or after method step D3). In general, it is expedient to apply more layers if they are formed to be thinner. It is thus possible to apply many layers on top of one another, as long as no peeling effect of the layers occurs.

Therefore, several, even different, conversion layers can be produced on the substrate. The individual crystalline or amorphous layers can each have different thicknesses and/or different levels of dopant concentration and/or different dopants. Therefore, it is possible, e.g., for a larger dopant concentration to be produced in all of the conversion layers in very thin and thus transparent individual layers in each case. It is also possible to apply several layers which are produced from the same solutions, in order to enhance the effect of the radiation conversion by combining these produced conversion layers.

A method is thus provided, in which a solution is applied, e.g., to a radiation-converting substrate. The solution contains a mixture of liquid metal precursors and liquid dopant precursors, in one embodiment also dispersed, nanopowder-like dopant precursors which by means of hydrolysis and condensation become a gel and after thermal treatment produce a luminescent, crystalline or amorphous conversion layer. The radiation-converting conversion layer can be used as a modifying radiation conversion layer, in order to adapt the radiation, which is converted by the radiation-converting substrate, even more precisely to the desired color shade.

The conversion layer can convert, e.g., small proportions of white-colored radiation to blue-colored or yellow-colored radiation, so that a cool-white radiation results. If a warm-white radiation is desired, the conversion layer can be formed in such a manner that small proportions of white radiation are converted into red shades or green shades.

The method demonstrates a simple technology for applying a color-modifying conversion layer to a converter layer, the substrate. However, the substrate can also be a layer which is inactive with respect to radiation. The conversion layer on the substrate is then the only radiation conversion layer which converts the radiation.

This method can be used to produce particularly thin conversion layers, e.g., 10 nm thick layers, which is not possible with conventional methods. The small thickness of the layers makes it possible to adjust the desired color shade very precisely by means of radiation conversion.

The method used to produce such thin conversion layers also offers the opportunity to apply also non-transparent, e.g., non-cubic, materials as a very thin layer, with which light transmission through the layer is only slightly reduced or is not reduced at all.

A radiation conversion element is also provided which is produced in accordance with a method according to one of the embodiments stated above and comprises a substrate and at least one conversion layer on the substrate. In one embodiment, the radiation conversion element can be transparent. Therefore, radiation which is emitted, e.g., by a semiconductor chip, on which the radiation conversion element is applied, can exit unhindered through the radiation conversion element, and at the same time the wavelength of the radiation can be converted.

The substrate can convert radiation or can be inactive with respect to radiation. A radiation-converting substrate can comprise inorganic material. It can be, e.g., a ceramic containing radiation-converting substances, a luminescent glass or a glass ceramic. If ceramics are used as the substrate, higher temperatures can be applied during the thermal treatment in method step D), without thereby damaging the substrate. For example, the ceramic used can be a YAG-ceramic which is stable at temperatures of up to 1850° C. If glasses are used as the substrate, the temperature in method step D) must be below the glass transition temperature. Soda-lime glass has, e.g., a glass transition point of 520 to 600° C. and silica glass approximately 1175° C.

An inorganic, radiation-converting substrate is favorable if further functional layers are to be deposited thereon. Inorganic, radiation-converting substrates thus permit the application, e.g., of additional inorganic functional layers which have to be produced at higher temperatures, in order to produce their functional properties. Therefore, an inorganic, radiation-converting substrate is thus also suitable for the application of a conversion layer by means of the aforementioned method which comprises a thermal treatment.

However, the substrate can also have non-radiation-converting properties and can be used merely as a substrate for the application and production of the conversion layer. In this case, the conversion layer is the only radiation-converting layer in the radiation conversion element.

The conversion layer can have a crystalline or amorphous structure. This is determined by the aforementioned production method. A metal having a proportion of 0.05 mol. % to 8 mol. %, in particular of 1 mol. % to 5 mol. % can be incorporated in the crystalline or amorphous structure. The metal can be selected from a group comprising Eu, Ce, Ir, Er and Cs. Depending upon the concentration of these metals which are dopants, in the conversion layer more or less of the radiation passing through the conversion layer is converted. The color, i.e., the wavelength of the radiation exiting the conversion layer can thus be adapted by the concentration of the dopants in the conversion layer.

The conversion layer can have a thickness which is selected from the range of 10 nm to 5 μm. The conversion layer can have, e.g., 10 nm. In this case, several conversion layers can be applied on the substrate one on top of the other, in order to enhance the effect of the radiation conversion.

Good adhesion between the substrate and the conversion layer can be achieved by the production method. By means of the hydrolysis and condensation which take place in method step C), bonds can also be produced between an inorganic substrate and the cross-linked gel layer. These bonds are retained even during the subsequent thermal treatment in method step D), whereby a covalent bond is formed between the conversion layer and the substrate. The rougher the substrate is formed, the more bonds to the gel can result, and the better the adhesion of the conversion layer on the substrate. These bonds can be, e.g., bonds between OH-groups of the substrate and of the gel.

The surface of the conversion layer can also be modified in a convenient manner, so that optionally a roughness can be produced which improves the exit of radiation from the conversion layer.

Finally, an optoelectronic component is also provided which contains a carrier, at least one radiation-emitting semiconductor chip on the carrier and a radiation conversion element in accordance with the aforementioned properties on the semiconductor chip. The radiation conversion element can convert the radiation emitted by the semiconductor chip. This can occur either by conversion by means of a radiation-converting substrate and a converting modification by means of the conversion layer, or solely by means of the conversion layer, if the substrate is inactive with respect to radiation and the conversion layer is the only radiation conversion layer.

An optoelectronic component which is configured in this manner has improved fine-tuning of the emitted radiation, which means that the desired wavelength of the emitted radiation can be adjusted precisely.

This type of optoelectronic component can be, e.g., an LED.

### BRIEF DESCRIPTION OF THE DRAWINGS

The invention will be explained in even greater detail with reference to the Figures and the exemplified embodiment.

FIG. 1 shows a schematic side view of an optoelectronic component; and

FIG. 2 shows a diagram of the method steps of the method for producing a radiation conversion element.

### DETAILED DESCRIPTION OF ILLUSTRATIVE EMBODIMENTS

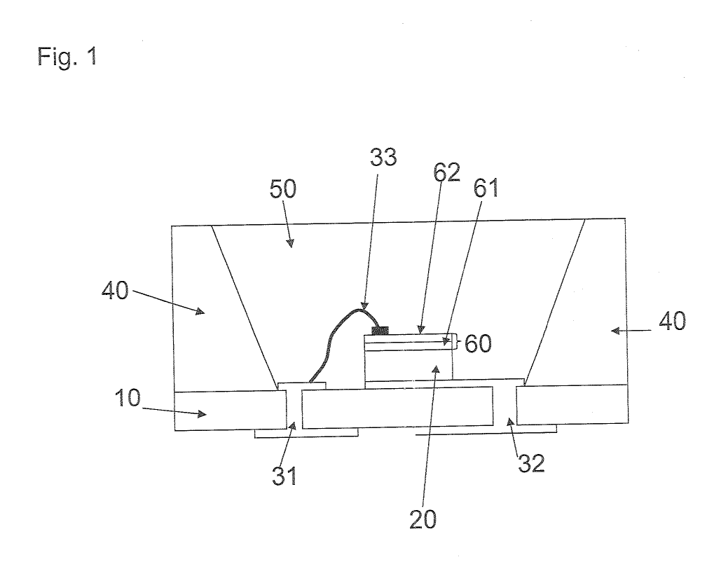

FIG. 1 shows the schematic side view of an optoelectronic component which comprises a support 10, a radiation-emitting semiconductor chip 20, a first and second contacting 31 and 32, a housing 40, a potting 50, a bond wire 33 and a radiation conversion element 60. The radiation conversion element 60 contains a substrate 61 and a conversion layer 62. The substrate 61 can itself be radiation-converting or inactive with respect to radiation. The conversion layer 62 is a radiation-converting layer and depending upon the configuration of the substrate can effect a modification of the wavelength of the radiation converted by the substrate, or can be the only radiation conversion layer. The semiconductor chip 20 can emit radiation of a wavelength which is converted into a desired wavelength by the radiation conversion element 60. The radiation conversion element 60 and also the potting 50 are formed to be transparent.

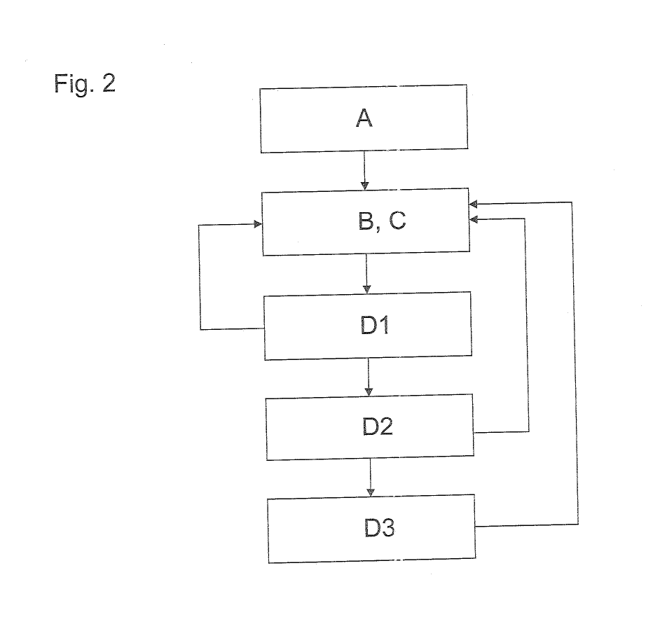

An example of the production of a conversion layer 62 on a substrate 61 is described hereinafter. Reference can be made to FIG. 2 for steps A, B, C, D1, D2 and D3.

Firstly, a solution is prepared which contains a mixture of metal precursors and luminescent dopant precursors. Metal precursors can comprise metal alkoxides, metal acetates, metal chlorides or metal nitrates. The dopant precursors can also contain metal alkoxides, metal acetates, metal chlorides and metal nitrates. The metals of the metal precursors comprise one or several of Al, Si, Ti and Zr, the metals of the dopant precursors comprise one or several of Eu, Ce, Ir, Er and Cs. The precursors can be stabilized prior to mixing thereof, in order to achieve simple handling of the solution and to avoid the formation of secondary phases.

This solution is applied, by means of spin coating, dip coating or spray coating, to a substrate, e.g., an inorganic substrate, which is formed from a ceramic, a glass or a glass ceramic. The solution on the substrate condenses and hydrolyses at room temperature to form a gel and is then dried for several minutes at 110° C. A high degree of cross-linking is thereby formed in the gel layer. The drying step can be repeated several times, in order to obtain the preferred layer thickness.

The substrate coated in this manner is then calcined in an oxygen atmosphere at temperatures of up to 600° C., in order to remove organic moieties in the gel and to permit the formation of an inorganic, amorphous network.

The calcined network on the substrate is then subjected to pyrolysis at higher temperatures, in order to permit crystallization of the amorphous layer. The atmosphere during the pyrolysis can be an oxygen, nitrogen or forming gas atmosphere. The atmosphere is selected depending upon how the material of the amorphous layer is composed, which stoichiometric ratios are present and the nature of the oxidation states of the dopants.

The intensity of the radiation conversion by the conversion layer depends upon the thickness of the conversion layer as well as upon the concentration of the dopant in this layer. The thickness of the conversion layer can be determined by means of the application technique in method step B), the viscosity of the solution, i.e., the amount of solvent in the solution provided in method step A), and the number of conversion layers produced. The thicker the layer and the higher the concentration of dopants, the higher the intensity of the radiation conversion, that is to say, the more the radiation is displaced entirely in the direction of higher or lower wavelengths.

The parameters of the application technique, e.g., the spinning speed or time, can be varied, in order to produce thicker or thinner conversion layers. Thicker layers can be provided, in which already cross-linked solutions having a correspondingly high viscosity are provided.

If the coating procedure is repeated several times, the conversion layers can likewise be formed to be thicker. Repetitions are possible after drying of the layer in method step D1), after calcination in method step D2) or after pyrolysis in method step D3). These possibilities, when a further solution for forming a further conversion layer can be applied, are also shown in FIG. 2 where in addition method steps A) providing the solution and method steps B) and C) applying the solution and hydrolyzing and condensing it are also provided before method step D1).

The invention described in this case is not limited by the description using the exemplified embodiments. Rather, the invention includes any new feature and any combination of features included in particular in any combination of features in the claims, even if this feature or this combination itself is not explicitly stated in the claims or exemplified embodiments.

1-15. (canceled)

16. A method for producing a radiation conversion element, the method comprising:
providing a substrate;
providing a stable solution that comprises luminescent dopant precursors;
applying the solution to the substrate;
hydrolyzing and condensing the solution to form a gel; and
thermally treating the gel to form a conversion layer on the substrate.

17. The method according to claim 16, wherein a solvent and metal precursors are included with the stable solution.

18. The method according to claim 17, wherein for the stable solution comprises metal precursors selected from the group consisting of metal alkoxides, metal acetates, metal chlorides and metal nitrates.

19. The method according to claim 16, wherein the dopant precursors comprise precursors selected from the group consisting of metal alkoxides, metal acetates, metal chlorides and metal nitrates of the metals Eu, Ce, Ir, Er and Cs.

20. The method according to claim 16, wherein applying the solution to the substrate comprises performing a method selected from the group consisting of spin coating, dip coating and spray coating.

21. The method according to claim 16, wherein thermally treating the gel comprises:
drying the gel;
calcining the gel to form an amorphous layer; and
pyrolysing the amorphous layer to form the conversion layer.

22. The method according to claim 16, further comprising repeating the steps of applying the solution, hydrolyzing and condensing the solution to form a gel, and thermally treating the gel at least twice.

23. The method according to claim 16, wherein the substrate is radiation-converting.

24. The method according to claim 23, wherein the radiation-converting substrate comprises a ceramic containing radiation-converting substances, a luminescent glass or a glass ceramic.

25. A radiation conversion element, produced according to the method according to claim 16, the conversion element comprising the substrate and the conversion layer on the substrate.

26. The radiation conversion element according to claim 25, wherein the conversion element is transparent.

27. The radiation conversion element according to claim 25, wherein the substrate is a radiation-converting substrate.

28. The radiation conversion element according to claim 27, wherein the radiation-converting substrate has an inorganic material.

29. The radiation conversion element according to claim 28, wherein the radiation-converting substrate is a ceramic containing radiation-converting substances, a luminescent glass or a glass ceramic.

30. The radiation conversion element according to claim 25, wherein the substrate is inactive with respect to radiation.

31. The radiation conversion element according to claim 25, wherein the conversion layer has a crystalline or amorphous structure.

32. The radiation conversion element according to claim 31, wherein a metal selected from a the group consisting of Eu, Ce, Ir, Er and Cs and having a proportion of 0.05 mol. % to 8 mol. % is incorporated in the crystalline or amorphous structure.

33. The radiation conversion element according to claim 25, wherein the conversion layer has a thickness in the range of 10 nm to 5 p.m.

34. An optoelectronic component, comprising:
a carrier;
a radiation-emitting semiconductor chip on the carrier; and
a radiation conversion element according to claim 25 on the semiconductor chip.
